(19) United States
(12) Patent Application Publication
(10) Pub. No.: US 2010/0327879 A1
(43) Pub. Date: Dec. 30, 2010

(54) CIRCUIT TEST JIG AND CIRCUIT TESTING METHOD

(75) Inventor: Kenji YASUZAWA, Kawasaki (JP)

Correspondence Address: Fujitsu Patent Center;Fujitsu Management Services of America, Inc., 2318 Mill Road, Suite 1010, Alexandria, VA, 22314, US

(73) Assignee: FUJITSU LIMITED, Kawasaki-shi (JP)

(21) Appl. No.: 12/821,959

(22) Filed: Jun. 23, 2010

(30) Foreign Application Priority Data
Jun. 30, 2009 (JP) 2009-156304

(51) Int. Cl. G01R 31/02

(52) U.S. Cl. 324/537

(57) ABSTRACT

A circuit test jig used for a printed board that includes a circuit board on which a circuit is formed, the circuit test jig includes a holding plate disposed between the circuit board and the print board and holds a plurality of conductive members that transmit signals between a group of terminals of the printed board and a group of terminals of the circuit board, and an elastic plate in which through holes are formed therein disposed at least one of between the holding plate and the circuit board or between the holding plate and the printed board.

### CROSS-REFERENCE TO RELATED APPLICATION

This application is based upon and claims the benefit of priority of the prior Japanese Patent Application No. 2009-156304, filed on Jun. 30, 2009, the entire contents of which are incorporated herein by reference.

### FIELD

The embodiment discussed herein is directed to a circuit test jig and a circuit testing method.

### BACKGROUND

LSI (Large Scale Integrated circuit) chips are usually mounted on printed circuit boards by attaching glass ceramic substrates, to which the LSI chips are attached, to print boards by using solder balls. An overview of a conventional printed circuit board on which an LSI chip is mounted will be explained below.

FIG. 8 is a configuration diagram of a conventional printed circuit board 1 on which an LSI chip is mounted. FIG. 9 is an explanatory view illustrating an overview of a conventional circuit test that uses a socket. As illustrated in FIG. 8, an LSI chip 2 is attached to a heat sink 4 by an adhesive 3. The LSI chip 2 is also attached to a glass ceramic substrate 7 with a resin 6 that contains solder balls 5.

The LSI chip 2 and wiring patterns 8 of the glass ceramic substrate 7 are connected to each other using the solder balls 5 such that signals can be transmitted. On a print board 16, gold pads 11 are provided. Hereinafter, an assembly of the LSI chip 2, the adhesive 3, the heat sink 4, the solder balls 5, and the resin 6 will be referred to as an LSI assembly 1a.

In other words, the glass ceramic substrate 7 is provided with the wiring patterns 8 formed therein and with gold pads 9 corresponding to the number of wiring patterns. The gold pads 9 on the glass ceramic substrate 7, to which the LSI assembly 1a is attached, and the gold pads 11 on the print board 16 are attached to each other using solder balls 12 such that signals can be transmitted.

Circuit tests using a circuit test jig (for example, metal Pogo pins) instead of the solder balls 12 for examining, as a single product, the circuit operations of the LSI chip 2, which is mounted as a printed circuit board, are performed on the conventional printed circuit board 1 that is formed as described above.

As illustrated in FIG. 9, metal Pogo pins 20 that form a circuit test jig that is used in such circuit tests are used in a way that the metal Pogo pins 20 are fixed in a socket case 21a (FIG. 10) that forms a socket 21.

A circuit testing method using a socket will be explained below. FIG. 10 is an explanatory view of a conventional socket. FIG. 11 is an explanatory view explaining a conventional circuit testing method using a socket. FIG. 12 is an explanatory view explaining the drawbacks of the conventional circuit testing method.

As illustrated in FIGS. 9 and 10, the socket 21 is in the form of the socket case 21a that holds the metal Pogo pins 20. The socket case 21a includes a plane plate 22 and side plates 23 that stand on both sides of the plane plate 22. Through holes 24 (FIG. 10) are formed vertically in the plane plate 22. The through holes 24, which correspond to the number of the metal Pogo pins 20 and are provided in the socket case 21a, are formed in the plane plate 22. As illustrated in FIG. 10, the metal Pogo pins 20 are fixed in the through holes 24 that are formed in the plane plate 22.

As illustrated in FIG. 11, to test the operations of a circuit using a socket, a power supply pin (not illustrated) of the print board 16 is energized and pressure is then vertically applied to the LSI chip 2 by means of a pressure applying member 70. Thereafter, input signals are transmitted through signal pins (input terminals P₁) of the print board 16 via the metal Pogo pins 20. Output signals from the LSI chip 2 are then received from signal pins (output terminals P₂) of the print board 16 via the metal Pogo pins and it is thus determined whether the LSI chip 2 performs correct circuit operations.

With respect to this type of socket configuration, a buffer table connector using an elastic connector similar to a socket is disclosed.

However, in the case of the socket 21 that is used for the above conventional performance, it is difficult to perform stable performance tests with the metal Pogo pins 20 in the socket 21.

Specifically, because the LSI chip 2 is a heat-treated member that is manufactured by, for example, heating a ceramic and the print board 16 is a laminated member, the flatness tolerance may be caused during manufacturing in the LSI chip 2 and the print board 16. In other words, unevenness that cannot be absorbed with the strokes of the metal Pogo pins 20 are caused among a flat portion of the socket case 21a of the socket 21, and a flat portion of the glass ceramic substrate 7, on which the LSI chip 2 is attached, and a flat portion of the print board 16.

Specifically, in the portion A illustrated in FIG. 12, because the bottom surface of the glass ceramic substrate 7 is bulged towards the upper surface of the socket 21, the top end portions of the metal Pogo pins 20 greatly press against the gold pads 9 provided on the glass ceramic substrate 7, and accordingly large loads are concentrated thereon (the total pressure load is approximately 83 Kgf). This may damage the LSI chip 2 due to the concentrated loads and a contact failure between the gold pads 9, which are provided on the glass ceramic substrate 7, and the metal Pogo pins 20.

In the portion B illustrated in FIG. 12, because the bottom surface of the socket 21 and the upper surface of the print board 16 are separated by a gap, the back end portions of the metal Pogo pins 20 make contact with the gold pads 11 on the print board 16 with only a small contact pressure. This may cause a contact failure between the metal Pogo pins 20 and the gold pads 11 on the print board 16.

As illustrated in FIG. 12, when foreign matter such as dust gets in the spaces between the bottom surface of the socket 21 and the upper surface of the print board 16, adverse effects such as a contact failure may be caused between the metal Pogo pins 20 and the print board 16.

### [Patent Document 1] Japanese Patent No. 3197880.

### SUMMARY

According to an aspect of an embodiment of the invention, a circuit test jig used for a printed board that includes a circuit board on which a circuit is formed, the circuit test jig includes: a holding plate disposed between the circuit board and the print board and holds a plurality of conductive members that transmit signals between a group of terminals of the printed board and a group of terminals of the circuit board; and an elastic plate in which through holes are formed therein disposed at least one of between the holding plate and the circuit board or between the holding plate and the printed board.

According to another aspect of an embodiment of the invention, a circuit testing method for a printed board that includes a circuit board on which a circuit is formed, the method includes: arranging an elastic plate between the circuit board and a holding plate disposed between the circuit board and the printed board and holds a plurality of conductive members that transmit signals between a group of terminals of the printed board and a group of terminals of the circuit board; providing the circuit board and the printed board such that the conductive members held by the holding plate are connected at one side to the group of terminals of the circuit board and such that the conductive members are connected at the other side to the group of terminals of the printed board; and testing the circuit board by transmitting signals between the circuit board and the printed board via the conductive members.

The object and advantages of the embodiment will be realized and attained by means of the elements and combinations particularly pointed out in the claims.

It is to be understood that both the foregoing general description and the following detailed description are exemplary and explanatory and are not restrictive of the embodiment, as claimed.

### BRIEF DESCRIPTION OF DRAWINGS

FIG. 1 is a perspective view of an internal configuration of a printed board on which a socket is arranged according to a first embodiment;

FIG. 2 is a cross-sectional view of an internal configuration of the socket illustrated in FIG. 1;

FIG. 3A is a plane view of a buffer sheet;

FIG. 3B is a side view of the buffer sheet;

FIG. 4 is an explanatory view of a metal Pogo pin;

FIG. 5 is an explanatory view of the printed board on which the socket is arranged;

FIG. 6 is an enlarged view of the portion X illustrated in FIG. 5;

FIG. 7 is a flowchart of a circuit testing method using a socket;

FIG. 8 is a configuration diagram of a conventional printed board on which an LSI chip is mounted;

FIG. 9 is an explanatory view illustrating an overview of a conventional circuit test using a socket;

FIG. 10 is an explanatory view of a conventional socket;

FIG. 11 is an explanatory view explaining a conventional circuit testing method using a socket; and

FIG. 12 is an explanatory view explaining drawbacks of a conventional circuit testing method.

### DESCRIPTION OF EMBODIMENT(S)

Preferred embodiments of the present invention will be explained with reference to accompanying drawings. A first embodiment does not limit the socket that the present application discloses.

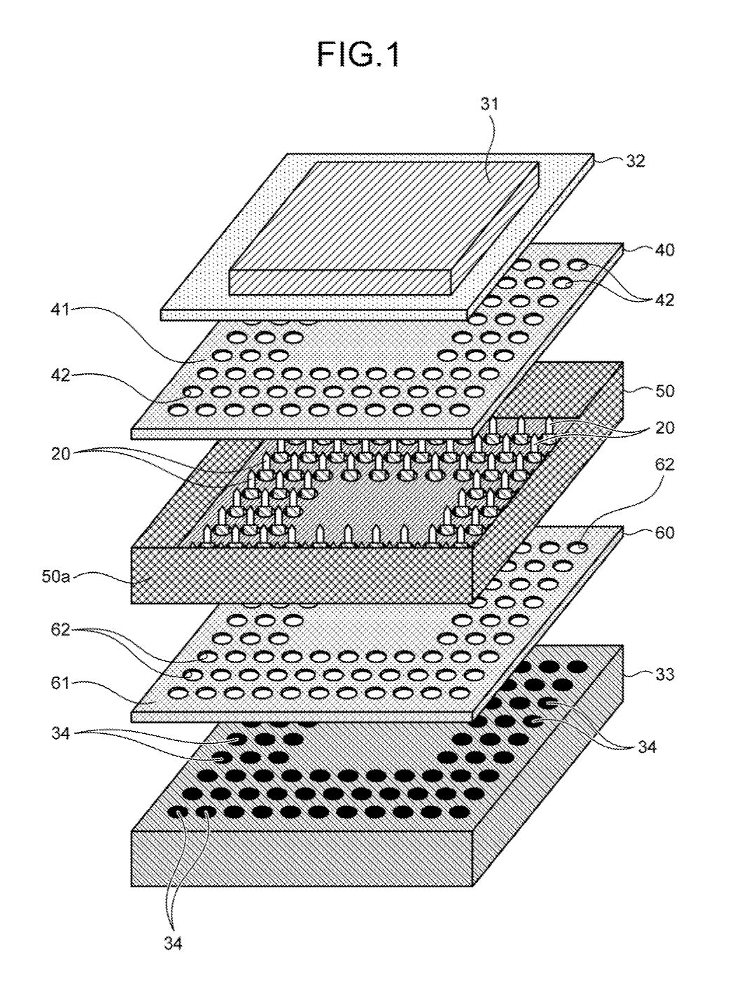

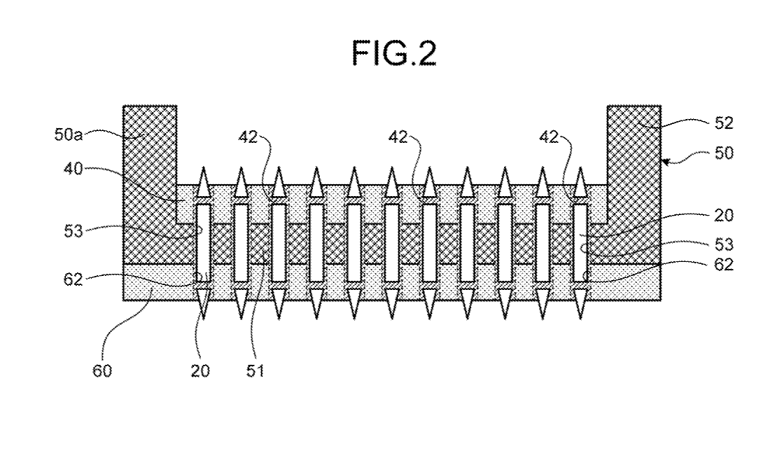

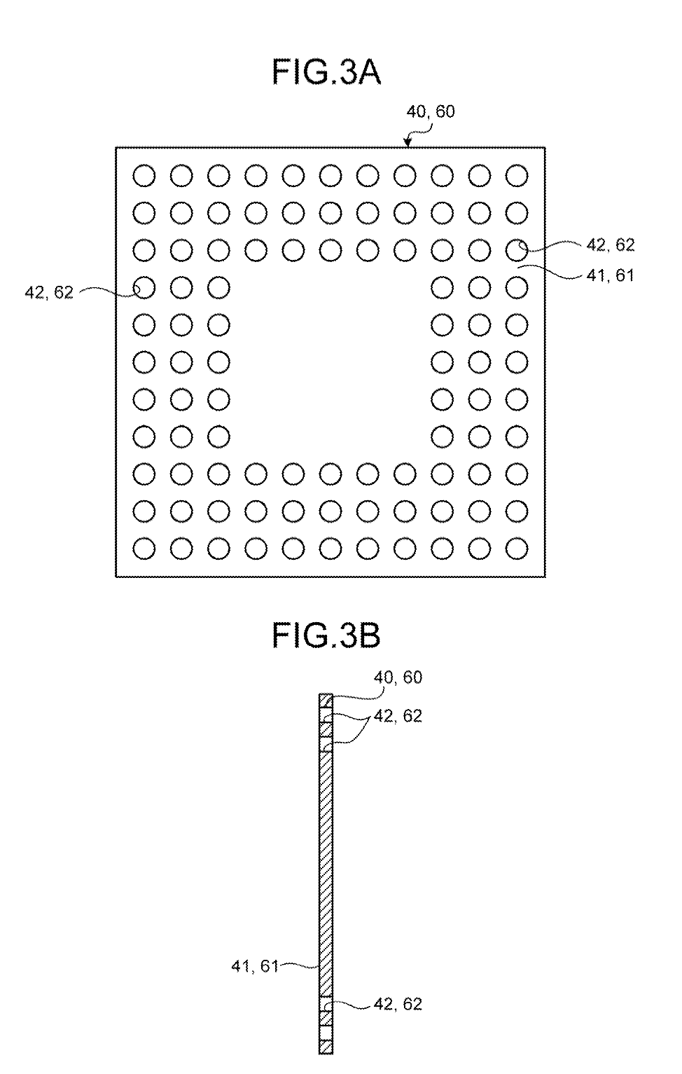

First, an overview of a configuration of a socket according to a first embodiment is explained. FIG. 1 is a perspective view of an internal configuration of a printed board on which the socket according to the first embodiment is arranged. FIG. 2 is a cross-sectional view of an internal configuration of the socket illustrated in FIG. 1. FIG. 3A is a plane view of a buffer sheet and FIG. 3B is a side view of the buffer sheet.

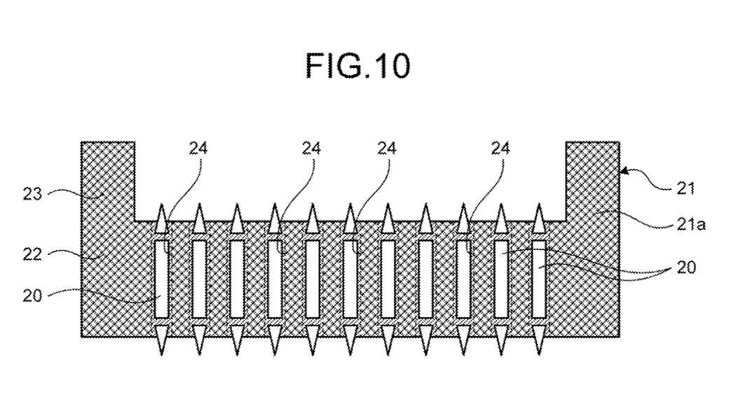

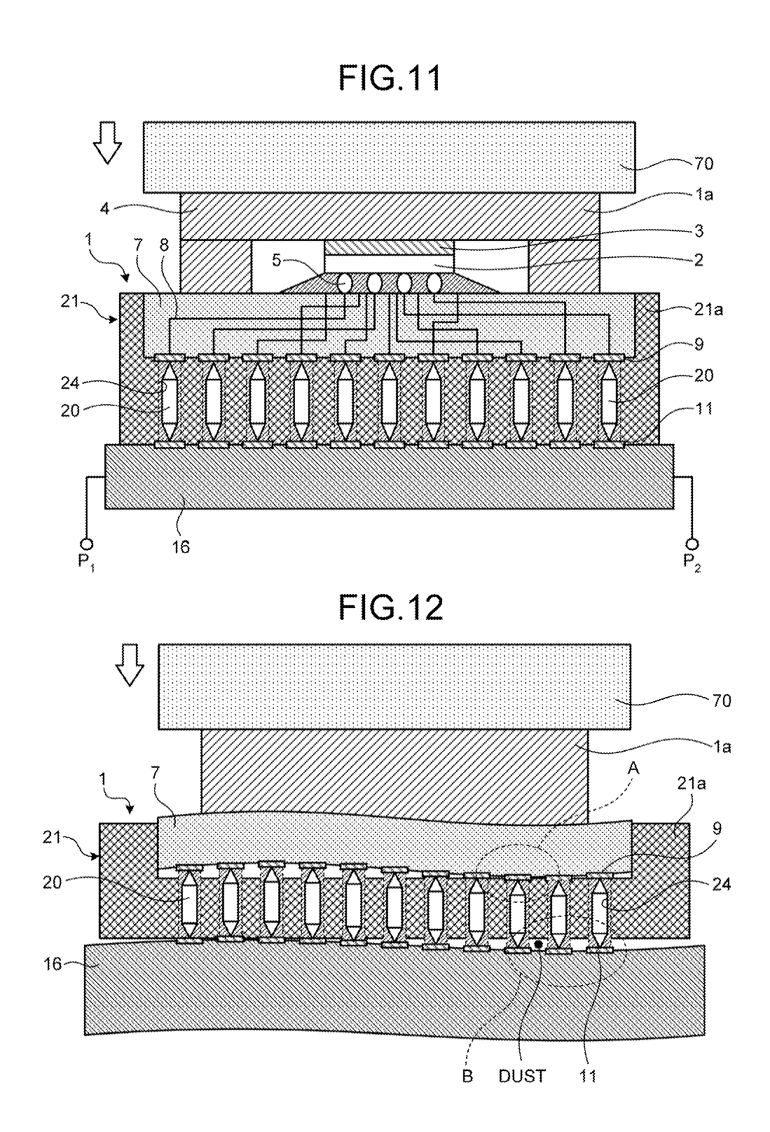

As illustrated in FIG. 1, in the first embodiment, a socket 50 is fixed between a glass ceramic substrate 32 (“circuit board”), to which an LSI chip 31 is attached, and a print board 33 (“printed board”) and a circuit test for the LSI chip 31 is performed. Regarding the configuration of the socket 50 according to the first embodiment, detailed explanations on members similar to those of the conventional socket 21 (see FIG. 10) will be omitted.

As illustrated in FIGS. 1 and 2, in the socket 50 according to the first embodiment, a buffer sheet 40 and a buffer sheet 60 are positioned respectively on the upper surface of a socket case 50a and on the upper surface of the print board 33. In other words, the buffer sheets 40 and 60 are arranged respectively in positions opposed to the socket case 50a of the socket 50 on the side of the LSI chip 31 and on the side of the print board 33.

As illustrated in FIGS. 1 and 2, the socket 50 includes the buffer sheets 40 and 60. The socket 50 is in the form of the socket case 50a that holds the metal Pogo pins 20. The socket case 50a includes a plane plate 51 and side plates 52 that stand on both sides of the plane plate 51. A plurality of through holes 53 that extend vertically (in the up-to-down/down-to-up direction in FIG. 2) are formed in the plane plate 51.

As illustrated in FIG. 2, the metal Pogo pins 20 are fixed in the through holes 53 that are formed in the plane plate 51. In addition, the buffer sheet 40 that is formed of an elastic member is provided on the upper surface of the plane plate 51. Similarly, the buffer sheet 60 that is formed of an elastic member is provided on the bottom surface of the plane plate 51.

As illustrated in FIGS. 3A and 3B, the buffer sheet 40 is in the form of a sheet body 41 that is formed in a square. Through holes 42 that penetrate through the sheet body 41 and in which the metal Pogo pins 20 (99 Pogo pins in FIG. 3A) are fixed, are formed in the sheet body 41. In other words, the through holes 42 are formed in positions corresponding to the arrangement of a plurality of gold pads 35 with which the glass ceramic substrate 32 to which the LSI chip 31 is attached, is provided.

Similarly, the buffer sheet 60 is in the form of a sheet body 61, and through holes 62 that penetrate through the sheet body 61 are formed in positions corresponding to the arrangement of the gold pads 35 that are provided on the print board 33. The buffer sheet 40 is an elastic member that deforms with a pressure load of approximately 60 kgf. A non-conductive sheet member is used for the buffer sheet 40. The buffer sheets 40 and 60 lead to sealing effects on the bottom surface of the socket 50 and prevent dust from getting in.

Elastic materials that start deforming with a pressure application of approximately 60 Kgf or more are used for the buffer sheets 40 and 60 according to the first embodiment. However, by selecting a material hardness of the buffer sheets 40 and 60 in accordance with the hardness or the size of the LSI chip 31 and the print board 33, various types of use and various loads (pressure loads) may be applied.

The glass ceramic substrate 32 is provided with a plurality of wiring patterns 8 that are formed therein and with the gold pads 35 corresponding to the number of the wiring patterns. When the metal Pogo ping 20 are fixed to the socket 50, the gold pads 35 that are provided on the glass ceramic substrate 32 make contact with the back end portions of the metal Pogo pins 20. The gold pads 35 are provided on the upper surface of the print board 33.

When the metal Pogo pins 20 are fixed to the socket 50, the gold pads 35 that are provided on the print board 33 make contact with the back end portions of the metal Pogo pins 20. In this manner, the LSI chip 21 and the print board 33 are configured such that signals can be transmitted via the metal Pogo pins 20 with which the socket 50 is provided.

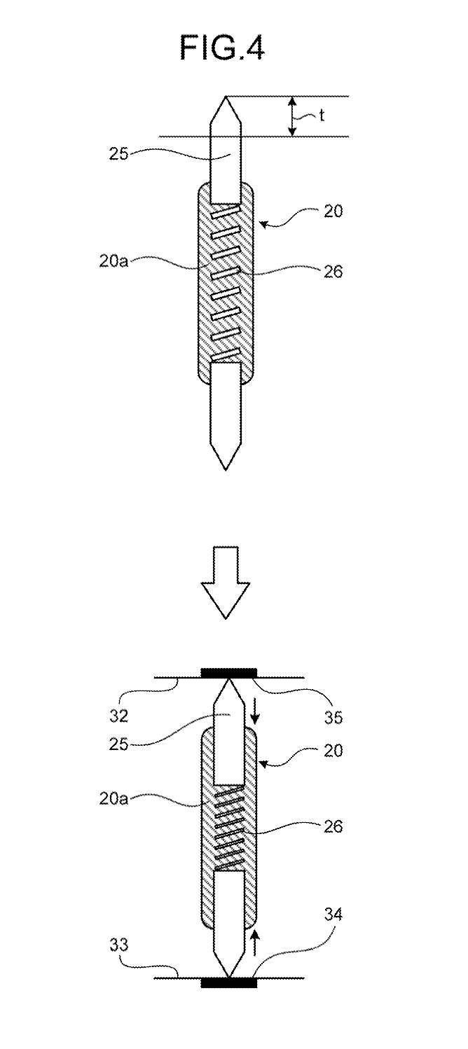

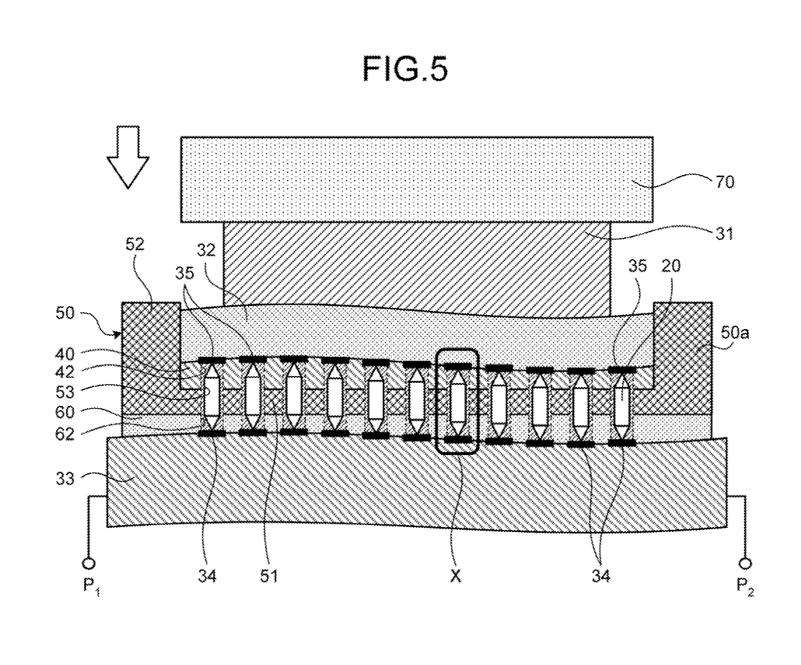

The metal Pogo pin 20 (FIG. 4) includes, in a pin case 20a, a pin body 25 and a compression spring 26 that is fitted into the pin body 25. When the metal Pogo pin 20 is fixed in the through hole 53 (FIG. 5) of the socket case 50a of the socket 50, the compression spring 26 compresses (by a distance t), so that the top end portion of the metal Pogo pin 20 makes contact with the gold pad 35 on the glass ceramic substrate 32 to which the LSI chip 31 is attached.

Similarly, when the metal Pogo pin 20 is fixed in the through hole 53 of the socket case 50a of the socket 50, the back end portion of the metal Pogo pin 20 makes contact with a gold pad 34 that is provided on the print board 33. Accordingly, predetermined signals can be transmitted between the print board 33 and the LSI chip 31 via the metal Pogo pin 20. The metal Pogo pin 20 is also referred to as a movable probe pin, a spring pin, a contact probe, or a contact pin.

As illustrated in FIG. 5, when the metal Pogo pins 20 are fixed to the socket 50, the column portions of the metal Pogo pins 20 penetrate through the through holes 53 that are formed in the socket case 50a and the top end portions of the metal Pogo pins 20 penetrate through the through holes 42 in the buffer sheet 40.

The top end portions of the metal Pogo pins 20 are connected to the gold pads 35 of the glass ceramic substrate 32. In contrast, the back end portions of the metal Pogo pins 20 penetrate through the through holes 62 of the buffer sheet 60. The back end portions of the metal Pogo pins 20 are connected to the gold pads 34 with which the print board 33 is provided.

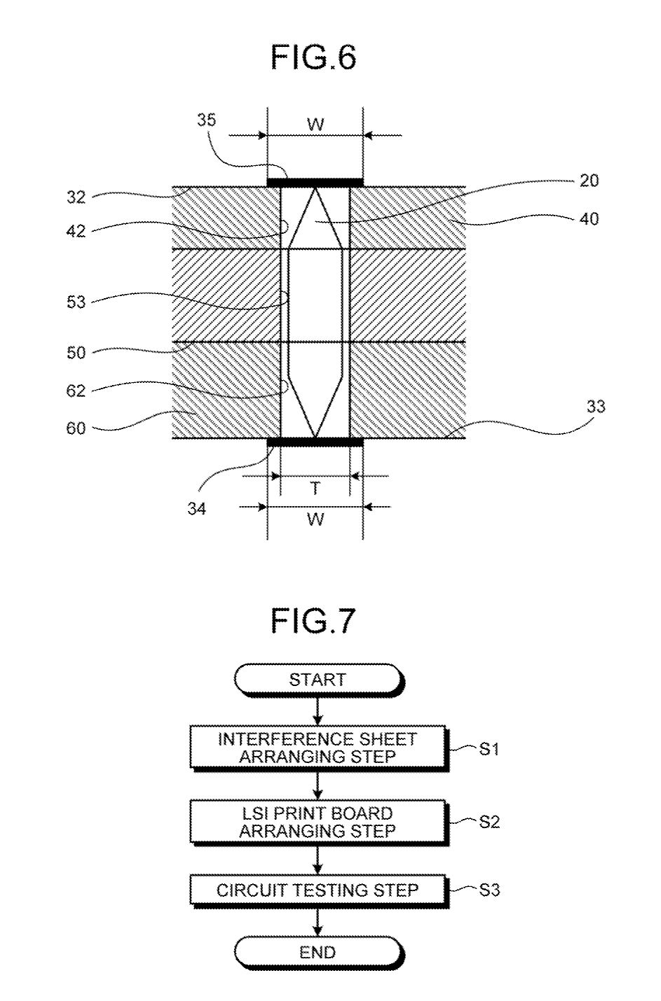

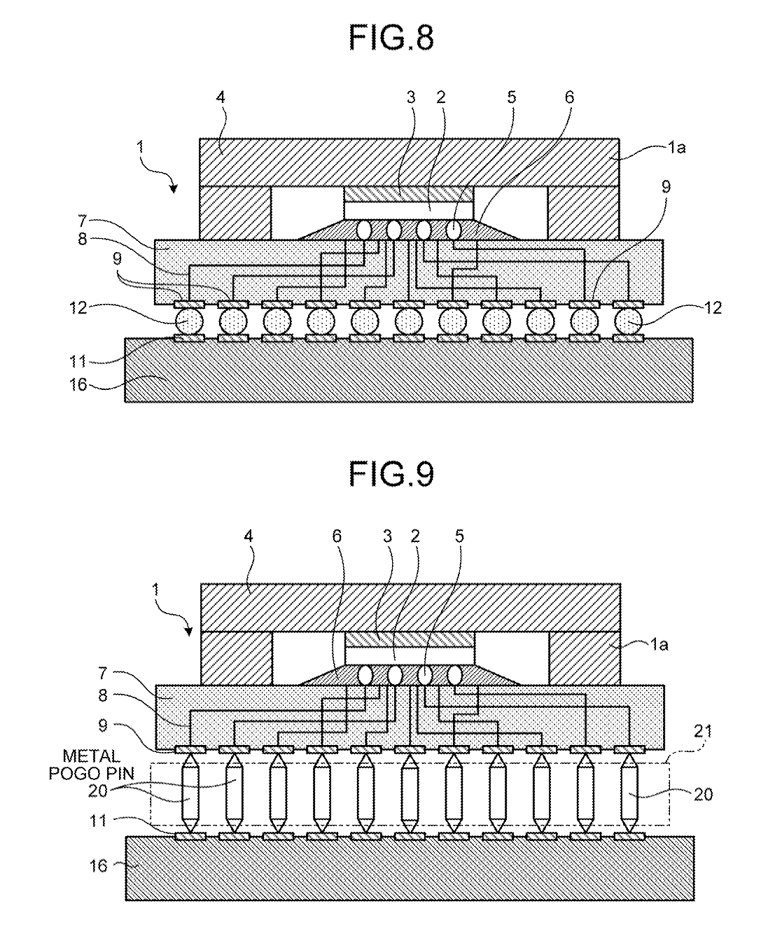

A width W (FIG. 6) of the gold pad 35 provided on the glass ceramic substrate 32 is set approximately the same as, or slightly wider than, a width T of the through hole 42 that is formed in the buffer sheet 40 (the width T of the through hole 42 ≦the width of the gold pad 35). By forming the gold pad 35 in the width W slightly larger than the width T of the through hole 42 in the buffer sheet 40, the area in which the gold pad 35 makes contact with the buffer sheet 40 increases, which absorbs the distortion tolerance of the plane surface due to deformation of the glass ceramic substrate 32, to which the LSI chip 31 is attached.

Similarly, a width W (FIG. 6) of the gold pad 34 that is provided on the print board 33 is set approximately the same as, or slightly wider than, a width T of the through hole 62 that is formed in the buffer sheet 60 (the width T of the through hole 62 ≦the width of the gold pad 34). By forming the gold pad 34 in the width W slightly larger than the width T of the through hole 62 of the buffer sheet 60, the area in which the gold pad 34 makes contact with the buffer sheet 60 increases, which absorbs the distortion tolerance of the plane surface due to deformation of the print board 33.

Circuit Testing Method Testing Circuit Using Socket

A circuit testing method using a socket according to the first embodiment will be explained. FIG. 7 is a flowchart of the circuit testing method using a socket according to the first embodiment. Hereinafter, it is provided that the circuit testing method using a socket according to the first embodiment circuit is performed by a test system that performs tests according to a predetermined procedure using the socket 50 (FIG. 5).

As illustrated in the flowchart of FIG. 7, in the circuit testing method using a socket according to the first embodiment, a buffer sheet arranging step (step S1), a print board arranging step (step S2), and a circuit testing step (step S3) are performed sequentially.

As illustrated in the flowchart in FIG. 7, in the circuit test system according to the first embodiment, the buffer sheet arranging step for arranging the buffer sheets 40 and 60 on the socket 50 is performed. The buffer sheet arranging step is a step for arranging the buffer sheets 40 and 60 respectively between the LSI chip 31 and the socket case 50a, which forms the socket 50, and between the socket case 50a and the print board 33.

Specifically, first, the interference sheet 60 is arranged in a position opposed to the print board 33 (FIG. 5). In other words, the buffer sheet 60 is arranged between the bottom surface of the plane plate 51 which forms the socket case 50a of the socket 50, and the upper surface of the print board 33. The metal Pogo pins 20 penetrate through the through holes 53 in the socket case 50a in the socket 50 and the back end portions of the metal Pogo pins 20 penetrate through and are fixed in the through holes 62.

The buffer sheet 40 is then arranged in a position opposed to the glass ceramic substrate 32 to which the LSI chip 2 is attached. Specifically, the buffer sheet 40 is arranged between the upper surface of the plane plate 51 which forms the socket case 50a of the socket (FIG. 5), and the bottom surface of the glass ceramic substrate 32.

The metal Pogo pins 20 penetrate through the through holes 53 of the socket case 50a in the socket 50 and the top end portions of the metal Pogo pins 20 penetrate through and fixed in the through holes 42.

As illustrated in the flowchart of FIG. 7, the circuit test system according to the first embodiment, an LSI print board arranging step for arranging the LSI chip 31 and the print board 33 on the socket 50 are performed. The LSI print board arranging step is a step for arranging the LSI chip 31 and the print board 33 in positions opposed to the socket 50.

Specifically, the LSI chip 31 is arranged with respect to the socket 50 such that the top end portions of the metal Pogo pins 20 which are held by the socket case 50a of the socket 50, connect respectively to the gold pads 35 on the glass ceramic substrate 32 to which the LSI chip 31 is attached.

The print board 33 is arranged with respect to the socket 50 such that the back end portions of the metal Pogo pins 20 which are held by the socket case 50a of the socket 50, connect respectively to the gold pads 34 on the print board 33.

When the metal Pogo pins 20 are fixed in the through holes 53 of the socket case 50a of the socket 50, the top end portions of the metal Pogo pins 20 make contact with the gold pads 35 on the glass ceramic substrate 32, to which the LSI chip 31 is attached. Similarly, the back end portions of the metal Pogo pins 20 make contact with the gold pads 34 that are provided on the print board 33. Accordingly, predetermined signals can be transmitted between the print board 33 and the LSI chip 31 via the metal Pogo pins 20.

As illustrated in the flowchart in FIG. 7, in the circuit test system according to the first embodiment, the circuit testing step is performed on the LSI chip 31 that is mounted on the print board 33. The circuit testing step is a step for testing the circuit performance of the LSI chip 31 by transmitting predetermined signals between the LSI chip 31 (the glass ceramic substrate 32) and the print board 33 via the metal Pogo pins 20.

Specifically, to test the circuit performance of the LSI chip 31 by using the socket 50, a power pin (not illustrated) of the print board 33 is activated and a pressure is vertically applied to the LSI chip 31 by means of the pressure applying member 70 (FIG. 5). Predetermined input signals are then transmitted to the LSI chip 31 via the metal Pogo pins 20 through a plurality of signal pins (input terminals P₁). Thereafter, output signals from the LSI chip 31 are received from signal pins (output terminals P₂) via the metal Pogo pins 20 and the circuit performance of the LSI chip 31 is determined based on the received signals.

As described above, the socket 50 according to the first embodiment holds the metal Pogo pins 20 that are formed between the print board 33 and the glass ceramic substrate 32 to which the LSI chip 31 is attached, and that allow a current flow between the metal Pogo pins 20 and the LSI chip 31 or the print board 33. The socket 50 also includes the interference sheets 40 and 60 on which the through holes 42 and 62 are provided through which the metal Pogo pins 20 which respectively correspond to the gold pads 34 and 35 provided on the glass ceramic substrate 32 and the print board 33, penetrate. The buffer sheets 40 and 60 absorb the distortion tolerance of the plane surface (manufacture tolerance according to materials) of the LSI chip 31 and the print board 33 and prevent dust from entering a space near the socket 50.

Because the metal Pogo pins 20 can have surface contact, loads concentrated on one point may be reduced, which results in affinity between the socket 50 and the LSI chip 31 or the print board 33 and contacts with stroke tolerance of the metal Pogo pins 20 can be achieved. This assures the stability in electric properties.

In addition, because the loads that are applied to the LSI chip 31 and the print board 33 due to pin load repulsion of the metal Pogo pins can be efficiently dispersed, the loads on the metal Pogo pins 20 can be reduced to support uniform contact of the metal Pogo pins 20.

The first embodiment of the circuit test jig and the circuit testing method are explained above. In addition to the first embodiment, the circuit test jig and the circuit testing method may be carried out in various different embodiments within the scope of the technical concepts that are described in the claims.

In the first embodiment, the socket 50 includes the square socket case 50a. Alternatively, the socket case 50a may be a rectangle of which length and width are different. In the first embodiment, the through holes 42 and 62 for fixing the metal Pogo pins 20 are formed in the buffer sheets 40 and 60 that are elastic sheets. Alternatively, the through holes 42 and 62 which are formed in the buffer sheets 40 and 60, may be not circular and a continuous oval through hole that can hold the metal Pogo pins 20 may be formed without providing a plurality of through holes in the buffer sheet. If the through holes formed in the buffer sheets for the metal Pogo pins 20 of the first embodiment are replaced with a continuous long hole, the buffer sheets may be manufactured easily.

According to an embodiment of the present invention, the flatness tolerance of the circuit board or the board substrate can be absorbed, and accordingly, application of a pressure to the metal Pogo pins can be dispersed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A circuit test jig used for a printed board that includes a circuit board on which a circuit is formed, the circuit test jig comprising:
a holding plate disposed between the circuit board and the print board and holds a plurality of conductive members that transmit signals between a group of terminals of the printed board and a group of terminals of the circuit board; and
an elastic plate in which through holes are formed therein disposed at least one of between the holding plate and the circuit board or between the holding plate and the printed board.

2. The circuit test jig according to claim 1, wherein the elastic plate is a non-conductive member.

3. The circuit test jig according to claim 1, wherein width of the terminal provided to the circuit board or the printed board is larger than the width of the through hole.

4. A circuit testing method for a printed board that includes a circuit board on which a circuit is formed, the method comprising:
arranging an elastic plate between the circuit board and a holding plate disposed between the circuit board and the printed board and holds a plurality of conductive members that transmit signals between a group of terminals of the printed board and a group of terminals of the circuit board;
providing the circuit board and the printed board such that the conductive members held by the holding plate are connected at one side to the group of terminals of the circuit board and such that the conductive members are connected at the other side to the group of terminals of the printed board; and
testing the circuit board by transmitting signals between the circuit board and the printed board via the conductive members.
